(19) United States
(12) Patent Application Publication
(10) Pub. No.: US 2026/0244112 A1
(43) Pub. Date: Aug. 20, 2026

(54) COMPONENT FOR A SYSTEM OF SEMICONDUCTOR TECHNOLOGY AND METHOD FOR PRODUCING A COMPONENT FOR A SYSTEM OF SEMICONDUCTOR TECHNOLOGY

(71) Applicant: Carl Zeiss SMT GmbH, Oberkochen (DE)

(72) Inventors: Arvid MACZEYZIK, Aalen (DE); Martin ELMER, Ellwangen (DE)

(21) Appl. No.: 19/639,640

(22) Filed: Apr. 6, 2026

Related U.S. Application Data
(63) Continuation of application No. PCT/EP2024/077702, filed on Oct. 2, 2024.

(30) Foreign Application Priority Data
Oct. 5, 2023 (DE) 10 2023 209 748.6

(51) Int. Cl. G03F 7/00

(52) U.S. Cl. CPC G03F 7/70508; G03F 7/70225

(57) ABSTRACT

A component (36, Mi) for a system of semiconductor technology (1) is provided with at least one electronic component containing information with respect to the component (36, Mi), for the purpose of contactless data exchange (50). The electronic component for contactless data exchange (50) is reversibly attached to the component (36, Mi).

### CROSS REFERENCE TO RELATED APPLICATIONS

This is a Continuation of International Application PCT/EP2024/0077702, which has an international filing date of Oct. 2, 2024, and which claims the priority of German Patent Application 10 2023 209 748.6, filed Oct. 5, 2023. The disclosures of both applications are Incorporated in their respective entireties into the present Continuation by reference.

### FIELD

The invention relates to a component for a semiconductor technology apparatus, wherein the component is provided with at least one electronic component part for contactless data exchange that comprises information relating to the component.

The invention also relates to a method for producing a component for a semiconductor technology apparatus, wherein the component is provided with an electronic component part for contactless data exchange that comprises information relating to the component.

### BACKGROUND

In the prior art, those apparatuses which are used to produce or test microstructured parts or the components required therefor are referred to as apparatuses for semiconductor technology. One example of such an apparatus is a photolithographic projection exposure apparatus.

Photolithography is used to produce microstructured parts, such as integrated circuits. The projection exposure apparatus used in the process comprises an illumination system and a projection system. The image of a mask (also referred to as a reticle) illuminated by the illumination system is projected, so as to reduce the size thereof, by the projection system onto a substrate, for example a silicon wafer, which is coated with a light-sensitive layer and is arranged in the image plane of the projection system, in order to transfer the mask structure to a light-sensitive coating on the substrate.

A method for tracking and identifying components of lithography systems as well as a corresponding lithography system are known from DE 10 2020 201 264 A1. In this case, the components are provided with a transponder having a data memory in which data relating to the respective component are stored. The transponder is configured to pick up wirelessly arriving signals from a reader and to respond with data from the data memory. The data memory of the transponder can store the wide variety of information relating to the component.

The described method can be used in principle in the field of semiconductor technology apparatuses and improves the component part tracking carried out in paper form up to that point, but it still has certain defects, such as the fact that the transponder could be regarded as disruptive when the component is subsequently used.

### SUMMARY

It is therefore an object of the present invention to provide a component for a semiconductor technology apparatus and a method for producing such a component which render it is possible to monitor the component even while avoiding disruption when using the component.

According to one formulation of the invention, this object is achieved by the features recited in the independent claim directed to a component.

The component according to this formulation of the invention for a semiconductor lithography apparatus is provided with at least one electronic component part for contactless data exchange that comprises information relating to the component. The electronic component part for contactless data exchange is reversibly attached to the component.

The electronic component part for contactless data exchange, which can be in the form of a transponder for example, renders possible an exchange of data containing information relating to the component with different receivers in order to be able to read out, forward or otherwise electronically process data relating to the component.

A particular advantage of the solution according to this formulation of invention is that the information relating to the component can be obtained from the electronic component part for contactless data exchange in a wide variety of ways and using a wide variety of devices, in particular without the need to approach the component within a certain distance or to hold a reader or the like to it. In fact, the location of the component can be determined very easily with suitable devices.

For example, this also makes it possible to easily locate the component within factory premises. For this purpose, sensors can be installed extensively on the factory premises, for example, which sensors come into contact with the electronic component part for contactless data exchange and obtain information from it.

Furthermore, such electronic component parts for contactless data exchange usually have a data memory in which all relevant information can be stored directly, with the result that information, for example relating to maintenance, repair or certain processing steps, can be retrieved directly and in situ, in particular without the need to leave a clean room and/or a vacuum environment.

Since, according to this formulation of the present invention, the electronic component part for contactless data exchange is reversibly attached to the component, it can be removed from the component, for example before delivering the component to a customer. This is advantageous, for example, if the information contained in the electronic component part for contactless data exchange is in-house information that is not intended to be passed on to third parties. Furthermore, this solution avoids any disruption that may result during subsequent use of the component by a customer, since the electronic component part for contactless data exchange may have already been disconnected from the component at this point in time.

In a very advantageous development of the invention, provision may be made for the component to be composed of a glass ceramic, in particular Zerodur®. Especially in the case of a component made of a glass ceramic, in particular Zerodur, the solution according to this formulation of the invention can be used very advantageously, since such components may require a particularly high level of information exchange.

A further advantageous configuration of the invention may be that the electronic component part for contactless data exchange is arranged in a recess of the component and/or in a recess of a receiving element that receives the electronic component part for contactless data exchange and is attached to the component. This results in particularly good protection for the electronic component part for contactless data exchange, which is received in a kind of pocket, with the result that no damage to the electronic component part for contactless data exchange is to be expected, in particular even during production. In particular, if the electronic component part for contactless data exchange is arranged in a recess of a receiving element that receives the electronic component part for contactless data exchange and is attached to the component, it is possible to attach the electronic component part for contactless data exchange to the component quickly and easily and in a manner that can be released with minimal effort and without residue.

The protection of the electronic component part for contactless data exchange can be further increased if the recess with the electronic component part for contactless data exchange arranged therein is sealed with a covering element. In particular, this protects the electronic component part for contactless data exchange against any external influences that may occur during production, such as grinding, lapping or washing processes carried out on the component or coatings or processing chemicals applied to the component.

Furthermore, In one advantageous configuration of the invention, provision may be made for a cavity which is not occupied by the electronic component part for contactless data exchange within the recess to be filled with a sealant. This prevents movements, vibrations and the like of the electronic component part for contactless data exchange during transport operations or the like. This also prevents air inclusions. Air inclusions can also be prevented by attaching the electronic component part for contactless data exchange to the component in an evacuated environment.

In order avoid hindering both the method for producing the component and its subsequent use, provision may also be made for the electronic component part for contactless data exchange to be attached outside an optically relevant region of the component.

The solution according to the invention can be used in a particularly advantageous manner if the component is in the form of an optical element, in particular a lens, a mirror or a diffractive optical element, or a mechanical element, in particular a mount, a frame or a holding element for an element to be machined by the semiconductor technology apparatus.

A further formulation of the invention specifies a method for producing a component of a semiconductor technology apparatus.

In this method, the component is provided with an electronic component part for contactless data exchange that comprises information relating to the component. The electronic component part for contactless data exchange is reversibly attached to the component during the method.

The method according to the invention makes it possible to produce the component in a very simple manner, wherein, due to the reversibility of the process, it is particularly advantageous that the electronic component part for contactless data exchange can be removed from the component, as a result of which said component part no longer has to be present on the component in situations in which it is considered disruptive.

In a very advantageous development of the method, provision may be made for the component to be composed of a glass ceramic, in particular Zerodur. In a component made of a glass ceramic, In particular Zerodur, it is particularly complicated to reversibly attach such electronic component parts for contactless data exchange to the component, but this can be achieved with the method according to the invention.

A further advantageous configuration of the method may be that the electronic component part for contactless data exchange is connected to the component through additive manufacturing, adhesive bonding or laser welding so that the electronic component part for contactless data exchange can be separated from the component. In a further configuration of the method, the electronic component part is fixed to the component by magnetic force, but without being connected to the component by creating chemical bonds. A connection of the electronic component part for contactless exchange to the component through additive manufacturing, adhesive bonding, magnetic force or laser welding is advantageous in particular if the component is composed of a glass ceramic, in particular Zerodur, since this results in a secure and reversible connection between the electronic component part for contactless data exchange and the component. In this context, it is also possible for the electronic component part for contactless data exchange to be prefixed before connection to the component. For example, the prefixing can be carried out by one or more magnets.

Furthermore, an advantageous configuration of the method may be that the electronic component part for contactless data exchange is arranged in a recess of the component and/or in a recess of a receiving element that receives the electronic component part for contactless data exchange and is attached to the component, wherein the recess with the electronic component part for contactless data exchange arranged therein is sealed a covering element, and wherein the covering element or the receiving element attached to the component is connected to the component through adhesive bonding or laser welding. This enables particularly reliable protection of the electronic component part for contactless data exchange. The advantage of using a laser is, among other things, that no additional material is required, which prevents contamination, and that there is only minimal influence on the component.

In order to reliably avoid disruption caused by the electronic component part for contactless data exchange, provision may also be made for the covering element to be separated from the recess and/or for the electronic component part for contactless data exchange to be removed from the recess.

Furthermore, provision may be made for the electronic component part for contactless data exchange to be separated from the component after its use with laser cutting. With this method, it is particularly easy to separate the electronic component part for contactless data exchange and the component.

A further formulation of the invention relates to a semiconductor technology apparatus having at least one component according to the invention. Formulations of the invention also extend to an electronic component part produced using an appropriate semiconductor technology apparatus, with the component part preferably comprising structures in the micrometer and/or nanometer range.

In connection with the present application, any apparatus that can be used to produce or test microstructured parts or the components required therefor is referred to as a “semiconductor technology apparatus”. In addition to photolithographic projection exposure apparatuses, this also includes in particular inspection apparatuses, in particular for masks or wafers, as well as metrology systems that can be used to measure masks, wafers or any other optical elements, such as mirrors, in particular, in which case an increased variability in the illumination can improve the measurement results.

Features described in connection with one of the formulations of the invention, specifically given by components according to the invention, methods according to the invention, semiconductor technology apparatus according to the invention or the electronic component parts, are also advantageously implementable for the other formulations of the invention. Likewise, advantages mentioned in connection with one of the formulations of the invention can also be understood in relation to the other formulations of the invention.

Additionally, it should be noted that terms such as “comprising”, “having”, or “with” do not exclude other features or steps. Furthermore, terms such as “a(n)” or “the” which indicate single steps or features do not exclude a plurality of features or steps—and vice versa.

However, in a puristic embodiment of the invention, provision may also be made for the features introduced in the invention using the terms “comprising”, “having”, or “with” to be an exhaustive enumeration. Accordingly, one or more enumerations of features can be considered to be exhaustive within the context of the invention, for example respectively considered for each claim. For example, the invention can consist exclusively of the features specified in the Independent claims.

Exemplary embodiments of the invention will be described in more detail below with reference to the drawing.

The figures each show exemplary embodiments in which individual features of the present invention are illustrated in combination with one another. Features of an exemplary embodiment are also implementable independently of the other features of the same exemplary embodiment, and may readily be combined accordingly by a person skilled in the art to form further viable combinations and sub-combinations with features of other exemplary embodiments.

### BRIEF DESCRIPTION OF THE DRAWINGS

In the figures, functionally identical or equivalent elements are provided with the same reference signs.

In the Figures:

FIG. 1 shows a schematic illustration of a photolithographic projection exposure apparatus comprising a component according to the invention;

FIG. 2 shows a side view of a first embodiment of a component according to the invention in a first state;

FIG. 3 shows the component according to the invention from FIG. 2 in a second state;

FIG. 4 shows a plan view of a second embodiment of the component according to the invention; and

FIG. 5 shows a side view of a third embodiment of the component according to the invention.

### DETAILED DESCRIPTION

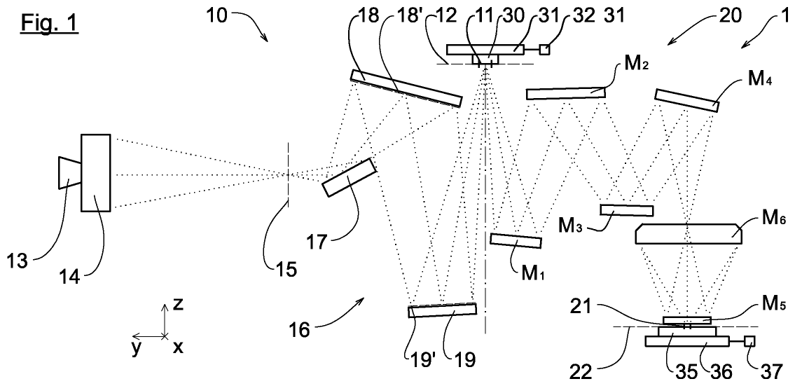

FIG. 1 illustrates a schematic meridional section through a photolithographic projection exposure apparatus 1 as an example of a semiconductor technology apparatus. In this case, the projection exposure apparatus 1 comprises an illumination system 10 and a projection system 20.

An object field 11 in an object plane or reticle plane 12 is illuminated with the illumination system 10. For this purpose, the illumination system 10 comprises an exposure radiation source 13, which, in the illustrated exemplary embodiment, emits illumination radiation at least comprising used light in the extreme ultraviolet (EUV) range, I.e. with a wavelength of between 5 nm and 30 nm in particular. The exposure radiation source 13 can be a plasma source, for example an LPP (laser produced plasma) source or a GDPP (gas discharge produced plasma) source. It can also be a synchrotron-based radiation source. The exposure radiation source 13 can also be a free electron laser (FEL).

The illumination radiation emerging from the exposure radiation source 13 is initially focused in a collector 14. The collector 14 can be a collector with one or more ellipsoidal and/or hyperboloidal reflection surfaces. The illumination radiation can be incident on the at least one reflection surface of the collector 14 with grazing incidence (GI), i.e. at angles of incidence of greater than 45°, or with normal incidence (NI), i.e. at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in principle, for the separation—including the structural separation-of the illumination system 10 into a radiation source module, comprising the exposure radiation source 13 and the collector 14, and the illumination optical unit 16 described below. In the case of a corresponding separation, the radiation source module and the illumination optical unit 16 then jointly form a modularly constructed illumination system 10.

The illumination optical unit 16 comprises a deflection mirror 17. The deflection mirror 17 may be a planar deflection mirror or alternatively a mirror with a beam-influencing effect going beyond the pure deflection effect. Alternatively or additionally, the deflection mirror 17 can be embodied as a spectral filter that separates a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optical unit 16 which is optically conjugate to the reticle plane 12 as a field plane, this facet mirror is also referred to as a field facet mirror.

The first facet mirror 18 comprises a multiplicity of micromirrors 18′ that are individually pivotable about two mutually perpendicular axes in each case, for the purpose of controllably forming facets which are each preferably configured with an orientation sensor (not illustrated) for determining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optical unit 16, thus resulting in a doubly faceted system, the fundamental principle of which is also referred to as a fly's eye integrator. If the second facet mirror 19—as in the illustrated exemplary embodiment—is arranged in a pupil plane of the illumination optical unit 16, it is also referred to as a pupil facet mirror. However, the second facet mirror 19 can also be arranged at a distance from a pupil plane of the illumination optical unit 16, as a result of which a specular reflector arises from the combination of the first and the second facet mirror 18, 19, as described for example in US 2006/0132747 A1, EP 1 614 008 B1 and U.S. Pat. No. 6,573,978.

The second facet mirror 19 need not in principle be constructed from pivotable micromirrors but rather can comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each preferably comprising an orientation sensor.

The individual facets of the first facet mirror 18 are imaged into the object field 11 with the aid of the second facet mirror 19, with this regularly only being approximate imaging. The second facet mirror 19 can be the last beam-shaping mirror or else actually the last mirror for the illumination radiation in the beam path upstream of the object field 11.

In each case one of the facets of the second facet mirror 19 is assigned to exactly one of the facets of the first facet mirror 18 for the purpose of forming an illumination channel for illuminating the object field 11. This can in particular result in illumination according to the Köhler principle.

The facets of the first facet mirror 18 are imaged overlaid on one another via a respective assigned facet of the second facet mirror 19, for the purpose of illuminating the object field 11. Here, the illumination of the object field 11 is as homogeneous as possible. It preferably has a uniformity error of less than 2%. Field uniformity can be achieved by overlaying different illumination channels.

By selecting the used illumination channels, which is possible without problems with a suitable setting of the micromirrors 18′ of the first facet mirror 18, it is still possible to set the intensity distribution in the entrance pupil of the projection system 20 described below. This Intensity distribution is also referred to as illumination setting. Incidentally, it may be advantageous here to arrange the second facet mirror 19 not exactly in a plane that is optically conjugate to a pupil plane of the projection system 20. In particular, the pupil facet mirror 19 can be arranged tilted relative to a pupil plane of the projection system 20, as is described in DE 10 2017 220 586 A1, for example.

In the arrangement of the components of the illumination optical unit 16 as illustrated in FIG. 1, however, the second facet mirror 19 is arranged in an area conjugate to the entrance pupil of the projection system 20. The deflection mirror 17 and the two facet mirrors 18, 19 are arranged tilted both vis-à-vis the object plane 12 and vis-à-vis one another in each case.

In an alternative embodiment (not illustrated) of the illumination optical unit 16, a transfer optical unit comprising one or more mirrors can additionally be provided in the beam path between the second facet mirror 19 and the object field 11. The transfer optical unit may in particular comprise one or two normal-incidence mirrors (NI mirrors) and/or one or two grazing-incidence mirrors (GI mirrors). Using an additional transfer optical unit, it is possible in particular to take account of different poses of the entrance pupil for the tangential and for the sagittal beam path of the projection system 20 described below.

It is alternatively possible for the deflection mirror 17 illustrated in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

For this purpose, the projection system 20 comprises a plurality of mirrors Mi, which are consecutively numbered in accordance with their arrangement in the beam path of the projection exposure apparatus 1.

In the example illustrated in FIG. 1, the projection system 20 comprises six mirrors M1 to M6. Alternatives with four, eight, ten, twelve or any other number of mirrors Mi are likewise possible. The penultimate mirror M5 and the last mirror M6 each have a passage opening for the illumination radiation, as a result of which the illustrated projection system 20 is a doubly obscured optical unit. The projection system 20 has an image-side numerical aperture that is greater than 0.3 and can also be greater than 0.6 and can be for example 0.7 or 0.75.

The reflection surfaces of the mirrors Mi can be in the form of freeform surfaces without an axis of rotational symmetry. However, the reflection surfaces of the mirrors Mi can alternatively also be designed as aspherical surfaces with exactly one axis of rotational symmetry of the reflection surface shape. Just like the mirrors of the illumination optical unit 16, the mirrors Mi can have highly reflective coatings for the illumination radiation. These reflective coatings can be designed as multilayer coatings, in particular with alternating layers of molybdenum and silicon.

The projection system 20 has a large object-image shift in the y-direction between a y-coordinate of a center of the object field 11 and a y-coordinate of the center of the image field 21. This object-image shift in the y-direction can be of approximately the same order as a z-distance between the object plane 12 and the image plane 22.

In particular, the projection system 20 can be designed to be anamorphic, i.e. it has different imaging scales βx, βy in the x- and y-directions in particular. The two imaging scales βx, βy of the projection system 20 are preferably (βx, βy)=(+/−0.25, /+−0.125). An imaging scale β of 0.25 corresponds here to a reduction with a ratio of 4:1, while an imaging scale B of 0.125 results in a reduction with a ratio of 8:1. A positive sign in the case of the imaging scale β means Imaging without image inversion; a negative sign means imaging with image inversion.

Other imaging scales are likewise feasible. Imaging scales βx, βy with the same sign and the same absolute magnitude in the x- and y-directions are also feasible.

The number of intermediate image planes in the x-direction and in the y-direction in the beam path between the object field 11 and the Image field 21 can be the same or different, depending on the embodiment of the projection system 20. Examples of projection systems 20 with different numbers of such intermediate images in the x-direction and y-direction are known from US 2018/0074303 A1.

In particular, the projection system 20 can comprise a homocentric entrance pupil. The pupil can be accessible. However, it can also be inaccessible.

A reticle 30 (also referred to as mask) arranged in the object field 11 is exposed by the illumination system 10 and transferred by the projection system 20 onto the image plane 21.

The reticle 30 is held by a reticle holder 31. The reticle holder 31 is displaceable in particular in a scanning direction with a reticle displacement drive 32. In the exemplary embodiment illustrated, the scanning direction runs in the y-direction.

A structure on the reticle 30 is Imaged onto a light-sensitive layer of a wafer 35 arranged in the region of the image field 21 in the image plane 22. The wafer 35 is held by a wafer holder 36. The wafer holder 36 is displaceable in particular in the y-direction with a wafer displacement drive 37. The displacement, firstly, of the reticle 30 with the reticle displacement drive 32 and, secondly, of the wafer 35 with the wafer displacement drive 37 can be synchronized with one another.

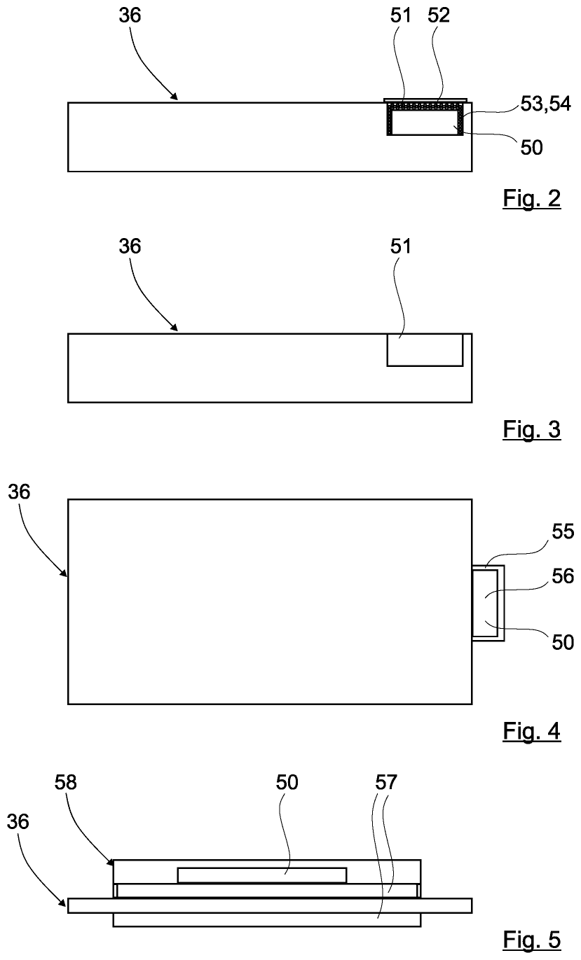

FIG. 2 shows a component for the semiconductor technology apparatus, in the present case of the projection exposure apparatus 1, which in the present case is in the form of the wafer holder 36 described above. However, the component described in more detail below could also be one of the mirrors Mi, a lens that is not illustrated, a mount that is not illustrated or another optically relevant component part of the projection exposure apparatus 1. Preferably, the component 36 or Mi is composed of a glass ceramic, in particular Zerodur.

The component 36 is provided with at least one electronic component part for contactless data exchange 50 that comprises information relating to the component 36. The electronic component part for contactless data exchange 50 is reversibly attached to the component 36. This means that the electronic component part for contactless data exchange 50 can be removed from the component 36 at any time and with little effort.

The electronic component part for contactless data exchange 50 can be designed, for example, as a transponder, in particular as an RFID or NFC transponder, and can have a data memory in which complex or detailed data relating to the component 36 and optionally also its subcomponents can also be stored, in particular also with regard to individualization of the component 36 and/or customer-specific features. The data memory can store a wide variety of data, in particular: data for identifying the type of component 36; ACTUAL data relating to the production of the component 36; data relating to individualization and/or customer-specific adaptation of the component 36; data relating to the affiliation of the component 36 to a specific lithography system, in particular an individualized and/or a customer-specific lithography system; data relating to properties of the component 36, by way of which it differs within the specifications from other components of the same type; measurement data relating to the component 36; data relating to a general overhaul, improvement, modification, refurbishment or retrofitting of the component 36; data relating to the service, commissioning, repair and/or maintenance of the component 36; data relating to certain production steps for the component 36, such as specific production methods for individual or all method steps; data relating to the process history; data relating to the material or materials of the component 36; data relating to the calibration of the component 36; data relating to the machining of the component 36; data relating to production features; data relating to product features; data relating to subcomponents of the component 36; data relating to the hardware of the component 36 and/or the type, configuration, arrangement, machining or state of the subcomponents of the component 36; data relating to suppliers; data relating to customers; data relating to additional information; the number of the component 36 assigned in a goods management system. One, a plurality or all of the aforementioned data can also be stored in the data memory for one subcomponent, a plurality of subcomponents, a group of subcomponents or all of the subcomponents of the component 36.

Preferably, the electronic component part for contactless data exchange 50 is attached outside an optically relevant region of the component 36. In the illustrated exemplary embodiment, in which the component is the wafer holder 36, the electronic component part for contactless data exchange 50 may be attached in an edge or corner region of the wafer holder 36.

In the embodiment of the component 36 illustrated in FIGS. 2 and 3, the electronic component part for contactless data exchange 50 is arranged in a recess 51 of the component 36, which can be previously generated by milling or another suitable method. The recess 51 with the electronic component part for contactless data exchange 50 arranged therein is closed, preferably hermetically sealed, with a covering element 52. The covering element 52 is preferably connected to the component 36 through adhesive bonding or laser welding. In addition, a cavity 53 formed in the recess 51 due to the electronic component part for contactless data exchange 50 being smaller than the recess 51, is filled with a sealant or a potting compound 54, whereby the electronic component part for contactless data exchange 50 is molded into the recess 51.

In addition to the procedure described above, the electronic component part for contactless data exchange 50 can be connected to the component 36, for example, through additive manufacturing, adhesive bonding, laser welding or another suitable method. This connection is such that the electronic component part for contactless data exchange 50 is separable from the component 36. This separation or disconnection can take place, in particular after using the electronic component part for contactless data exchange 50, in particular before delivery to a customer, for example through laser cutting. For example, an ultrashort pulse laser can be used in both laser welding and laser cutting. Disconnection by through breaking away is also possible. For this purpose, a predetermined breaking point, which can be mechanically or thermally separated, for example, or the like, can be provided in the region in which the electronic component part for contactless data exchange 50 is attached to the component 36. Furthermore, it is also possible to remove the electronic component part for contactless data exchange 50 from the component 36 so that the electronic component part for contactless data exchange 50 is then no longer functional or is destroyed. For example, this could be achieved by removing the electronic component part for contactless data exchange 50 from the component 36 through milling, lasering or in a similar manner. Furthermore, it is possible to produce inoperability of the electronic component part for contactless data exchange 50, for example by rendering it inoperable with an applied force, heat, acid or in another way. These options are also included in the “reversible attachment” of the electronic component part for contactless data exchange 50 to the component 36. Of course, it must be ensured that the component 36 is not damaged.

If the use of the electronic component part for contactless data exchange 50 also includes use during delivery or use by the customer, later separation is also feasible. FIG. 3 shows the state in which the electronic component part for contactless data exchange 50 is separated from the component 36. When separating the electronic component part for contactless data exchange 50 from the component 36, the covering element 52 can be separated from the recess 51, for example.

In the embodiment of the component, which is again designed as the wafer holder 36, Illustrated in FIG. 4, a receiving element 55 is provided and has a recess 56 which substantially corresponds with respect to its function to the recess 51 according to FIGS. 2 and 3. Accordingly, the electronic component part for contactless data exchange 50 is arranged in the recess 56 of the receiving element 55. In this embodiment, the receiving element 55 has a similar function to the covering element 52: The receiving element 55 is attached to the component 36 with the electronic component part for contactless data exchange 50 arranged in the recess 56 of the receiving element 55, wherein the recess 56 is sealed by this connection. The connection of the receiving element 55 to the component 36 can again be carried out by laser welding. It is also possible to use the sealant described above or the potting compound 54.

When separating the electronic component part for contactless data exchange 50 from the component 36, the receiving element 55 can be separated from the component 36, for example, in order thereby to remove the electronic component part for contactless data exchange 50 from the recess 56 and thus to separate it from the component 36. The separation of the receiving element 55 from the component 36 can be carried out, for example, through laser cutting.

Both the covering element 52 and the receiving element 55 are preferably composed of Zerodur, like the component 36. If the component 36 is not composed of Zerodur, the covering element 52 and the receiving element 55 should be composed of a material having the same or at least a similar coefficient of expansion as that of the material of the component 36.

FIG. 5 illustrates a further embodiment of the component 36, in which the electronic component part for contactless data exchange 50 is reversibly attached to the component 36 through magnetic force. In this case, the electronic component part for contactless data exchange 50 is connected to a magnetic component part 57 and is enclosed in a receiving element 58. The receiving element 58 in the present case consists of two half-shells which are connected to each other through laser welding and are preferably composed of glass or another suitable material. The receiving element 58 with the electronic component part for contactless data exchange 50 enclosed therein and the magnetic component part 57 is attached to the component 36 by abutting the component part 57 to the component 36 and arranging a further magnetic component part 57 on the opposite side. One of the magnetic component parts 57 is a magnet.

The above description of various embodiments has been given by way of example. From the disclosure given, those skilled in the art will not only understand the present invention and its attendant advantages but will also find apparent various changes and modifications to the structures and methods disclosed. The applicant seeks to cover all such changes and modifications as fall within the spirit and scope of the invention, as defined by the appended claims, and equivalents thereof.

### List of Reference Signs

1 Projection exposure apparatus
10 Illumination system
11 Object field
12 Object plane or reticle plane
13 Exposure radiation source
14 Collector
15 Intermediate focal plane
16 Illumination optical unit
17 Deflection mirror
18 First facet mirror
18′ Micromirror
19 Second facet mirror
19′ Micromirror
20 Projection system
21 Image field
22 Image plane
30 Reticle
31 Reticle holder
32 Reticle displacement drive
35 Wafer
36 Wafer holder
37 Wafer displacement drive
50 Electronic component part for contactless data exchange
51 Recess
52 Covering element
53 Cavity
54 Sealant
55 Receiving element
56 Recess
57 Magnetic component part
58 Receiving element

What is claimed is:

1. A component assembly for a semiconductor technology apparatus, comprising a component and at least one electronic component part configured for contactless data exchange that comprises information relating to the component, and a reversible attachment connecting the electronic component part for contactless data exchange to the component.

2. The component assembly as claimed in claim 1, wherein the component is composed of a glass ceramic.

3. The component assembly as claimed in claim 2, wherein the component is composed of Zerodur.

4. The component assembly as claimed in claim 1, wherein the electronic component part for contactless data exchange is arranged in a recess of the component and/or in a recess of a receiving element that receives the electronic component part for contactless data exchange and is attached to the component.

5. The component assembly as claimed in claim 4, wherein the recess with the electronic component part for contactless data exchange arranged therein is sealed with a covering element.

6. The component assembly as claimed in claim 4, wherein a cavity in the recess which is not occupied by the electronic component part for contactless data exchange within the recess is filled with a sealant.

7. The component assembly as claimed in claim 1, wherein the electronic component part for contactless data exchange is attached outside an optically relevant region of the component.

8. The component assembly as claimed in claim 1, wherein the component is an optical element or a mechanical element.

9. The component assembly as claimed in claim 1, wherein the optical element is a lens, a mirror or a diffractive optical element, and the mechanical element is a mount, a frame or a holding element.

10. A method for producing a component assembly for a semiconductor technology apparatus, comprising:
providing a component with an electronic component part for contactless data exchange,
providing information relating to the component to the electronic component part for contactless data exchange, and
reversibly attaching the electronic component part for contactless data exchange to the component.

11. The method as claimed in claim 10, further comprising fashioning the component from a glass ceramic.

12. The method as claimed in claim 11, wherein the glass ceramic is Zerodur.

13. The method as claimed in claim 10, further comprising connecting the electronic component part for contactless data exchange to the component through additive manufacturing, adhesive bonding, laser welding or magnetic force, so that the electronic component part for contactless data exchange is separable from the component.

14. The method as claimed in claim 10, further comprising:
arranging the electronic component part for contactless data exchange in a recess of the component and/or in a recess of a receiving element configured to receive the electronic component part for contactless data exchange,
attaching the electronic component part for contactless data exchange to the component, and
sealing the recess with the electronic component part for contactless data exchange arranged therein with a covering element,
wherein the covering element or the receiving element attached to the component is connected to the component through adhesive bonding or laser welding.

15. The method as claimed in claim 14, further comprising:
separating the covering element from the recess, and/or
removing the electronic component part for contactless data exchange from the recess.

16. The method as claimed in claim 10, further comprising:
separating, through laser cutting, the electronic component part for contactless data exchange from the component after a use.

17. A semiconductor technology apparatus comprising:
an optical element, and
at least one component assembly as claimed in claim 1,
wherein the optical element and the component assembly are arranged along an optical beam path.
